(19) United States
(12) Patent Application Publication
(10) Pub. No.: US 2012/0100641 A1
(43) Pub. Date: Apr. 26, 2012

(54) ETCHING APPARATUS AND ETCHING METHOD

(75) Inventors: Katsuhiko TACHIBANA, Fishkill, NY (US); Kenta Yoshinaga, Mie (JP)

(73) Assignee: KABUSHIKI KAISHA TOSHIBA, Tokyo (JP)

(21) Appl. No.: 13/278,651

(22) Filed: Oct. 21, 2011

(30) Foreign Application Priority Data
Oct. 22, 2010 (JP) 2010-237732

(51) Int. Cl. H01L 21/66; H01L 21/306

(52) U.S. Cl. 438/14; 156/345.24; 156/345.26; 257/E21.521

(57) ABSTRACT

According to an embodiment, an etching apparatus includes a reaction chamber, a vacuum pump connected to the reaction chamber through the gate valve, a holding unit which holds a processing subject, an etching gas supply unit, a heating unit, and a sublimation amount determining unit. The etching gas supply unit supplies an etching gas which forms a reaction product by reacting with the processing subject to the reaction chamber. The heating unit heats the processing subject to an equal or higher temperature than temperature at which the reaction product will be sublimated. The sublimation amount determining unit monitors a predetermined physical amount which changes depending on the degree of sublimation of the reaction product during the sublimation process using the heating unit, in which the physical amount is used as a sublimation-amount-dependent change value which changes over time.

### CROSS-REFERENCE TO RELATED APPLICATIONS

This application is based upon and claims the benefit of priority from Japanese Patent Application No. 2010-237732, filed on Oct. 22, 2010; the entire contents of which are incorporated herein by reference.

### FIELD

Embodiments described herein relate generally to an etching apparatus and an etching method.

### BACKGROUND

NAND type flash memories which are one type of nonvolatile semiconductor memory devices are formed generally in the following manner. First, a gate insulating film and a floating gate electrode film are stacked on a semiconductor substrate, and then trenches are formed which have a depth corresponding to the length from the floating gate electrode film to the semiconductor substrate and extend in a bit line direction. After a silicon oxide film is formed so as to fill the inside of the trench, all of the silicon oxide film which protrudes from the uppermost surface of the floating gate electrode film is removed through a Chemical Mechanical Polishing (CMP) process, and then the remaining silicon oxide film is etched to a predetermined depth through an Reactive Ion Etching (RIE) method. Accordingly, an element isolating film is formed which electrically isolates memory cell transistors, adjacent to one another in a word line direction, from one another. Subsequently, an inter-gate insulating film and a control gate electrode film are stacked on the floating gate electrode film and the element isolating film, followed by processing the films using an RIE method which processes the element isolating film, and stacked films ranging from the control gate electrode film to the gate insulating film into a pattern in which the films extend in the word line direction so that the memory cell transistors, adjacent to one another in the bit line direction, can be isolated from one another due to the form of the films extending in the word line direction. In the way described above, NAND type flash memories are formed.

Further, as a method of removing a thin film formed on a substrate, there is a known method in which a substrate having a thin film, as a removal subject, formed thereon is disposed inside a vacuum chamber, a reactive substance such as NH₃ and HF is introduced into the vacuum chamber and is caused to condense on the thin film so that the reactive substance and the thin film are allowed to react with each other for a predetermined period. This reaction produces a reaction product. Afterwards, the reactive substance and the reaction product are removed.

In nonvolatile semiconductor memory devices, it is desirable that heights of the element isolating films which isolate the memory cell transistors from one another are uniform within a memory cell array so that the element characteristics of the memory cell transistors become uniform within the memory cell array, and it is desirable that the top surfaces of the element isolating films are planarized.

### BRIEF DESCRIPTION OF THE DRAWINGS

FIG. 1 is a diagram schematically illustrating a configuration of an etching apparatus according to an embodiment;

FIG. 2 is a flowchart illustrating an example of a procedure of an etching method according to an embodiment;

FIGS. 3A to 3J are cross-sectional views schematically illustrating an example of a procedure of the etching method according to the embodiment;

FIG. 4 is a graph schematically illustrating a condition of the pressure inside a reaction chamber during the sublimation process;

FIGS. 5A and 5B are graphs schematically illustrating a condition of the pressure inside a reaction chamber during the sublimation process and a differential value of the pressure;

FIG. 6 is a diagram schematically illustrating a condition of the opening degree of a gate valve during a sublimation process; and

FIGS. 7A to 7F are schematic diagrams illustrating an effect of the etching method according to the embodiment.

### DETAILED DESCRIPTION

In general, according to one embodiment, an etching apparatus includes a reaction chamber, an exhaust unit which is connected to the reaction chamber through a gate valve, a holding unit which holds a processing subject, an etching gas supply unit, a heating unit, and a sublimation amount determining unit. The etching gas supply unit supplies etching gas, which may form a reaction product by reacting with the processing subject, into the reaction chamber. The heating unit heats the processing subject to an equal or higher temperature than temperature at which the reaction product will be sublimated. Then, the sublimation amount determining unit monitors a predetermined physical amount, changing depending on a degree of sublimation of the reaction product in the process of sublimation by the heating unit, as a sublimation-amount-dependent change value.

Exemplary embodiments of an etching apparatus and an etching method will be explained below in detail with reference to the accompanying drawings. Furthermore, the present invention is not limited to the following embodiments. Further, the cross-sectional views used in the following embodiments are schematically drawn, and the relation between the thickness and the width of the layer, the ratio between layers, or the like may be different from the actual one. Furthermore, the film thickness shown below is merely an example, and the invention is not limited thereto.

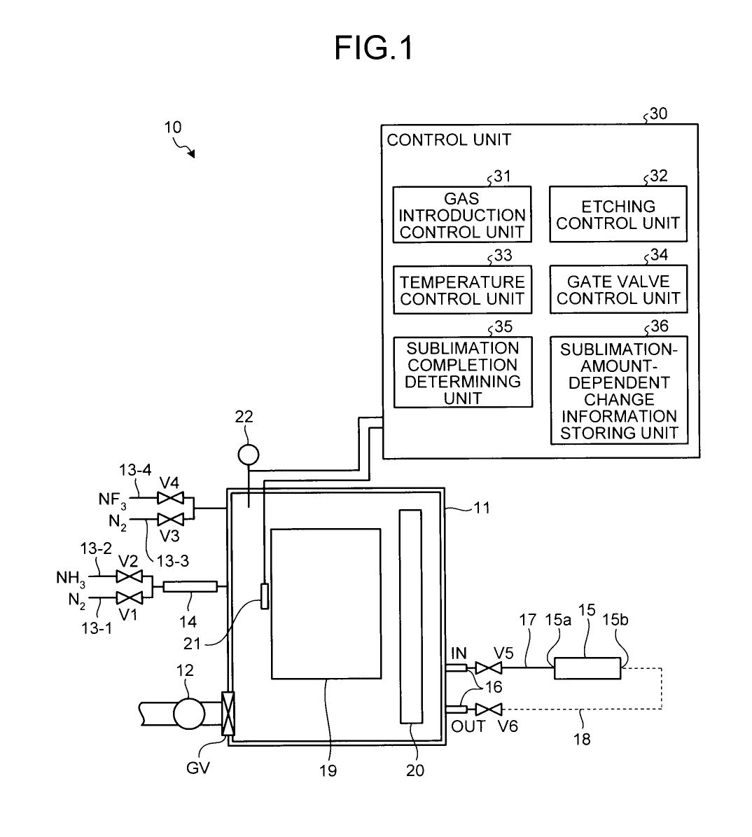

FIG. 1 is a diagram schematically illustrating a configuration of an etching apparatus according to an embodiment. As shown in the drawing, an etching apparatus 10 includes a reaction chamber 11 which forms a space for etching a processing subject, such as a wafer, by a gas. A vacuum pump 12 is connected to the reaction chamber 11 through a gate valve GV. The vacuum pump 12 is an exhaust unit that causes the reaction chamber 11 to enter a vacuum state by exhausting the gas therein.

Further, the reaction chamber 11 is equipped with pipes 13-1 to 13-4 which supply a gas into the reaction chamber 11. In this example, the reaction chamber 11 is equipped with the first and third pipes 13-1 and 13-3 that supplies N₂ gas, the second pipe 13-2 that supplies NH₃ gas, and the fourth pipe 13-4 that supplies NF₃ gas. The first and third pipes 13-1 and 13-3 are equipped with an N₂ gas supply unit (not shown), the second pipe 13-2 is equipped with an NH₃ gas supply unit (not shown), and the fourth pipe 13-4 is equipped with an NF₃ gas supply unit (not shown). Further, the first to fourth pipes 13-1 to 13-4 are respectively equipped with gas valves V1 to V4 switching the on/off state of the supply of the gas thereto.

In this example, the first and second pipes 13-1 and 13-2 are integrated with each other near the reaction chamber 11 and are connected as one pipe to the reaction chamber 11. An applicator 14 is equipped in the pipe between the gas valves V1 and V2 and the reaction chamber 11. The applicator 14 includes, for example, a quartz tube and a microwave application unit, and has the function of activating the NH₃ gas by applying a microwave to the quartz tube when introducing the NH₃ gas into the reaction chamber 11. Further, the third and fourth pipes 13-3 and 13-4 are also integrated with each other near the reaction chamber 11 and are then connected to the reaction chamber 11 as one pipe. Furthermore, the pipes 13-1 to 13-4, the NH₃ gas supply unit, and the NF₃ gas supply unit constitute an etching gas supply unit.

Furthermore, the reaction chamber 11 is equipped with a cooling pipe 16 which is a refrigerant passageway circulating refrigerant supplied from a chiller 15 which serves as a cooling unit. The cooling pipe 16 is equipped so as to be connected to, for example, the outer wall of the reaction chamber 11. A valve V5 is equipped on a pipe 17 connected between a refrigerant discharge port 15a of the chiller 15 and one end of the cooling pipe 16, and a valve V6 is equipped in a pipe 18 connected between a refrigerant collection port 15b of the chiller 15 and the other end of the cooling pipe 16. The refrigerant of which the temperature is adjusted in the chiller 15 is discharged from the refrigerant discharge port 15a, and the refrigerant moves (circulates) inside the cooling pipe 16, so that the reaction chamber 11 (the wall surface thereof) is cooled and maintained at a predetermined temperature. Furthermore, as the refrigerant, refrigerant which hardly volatilizes even in usage environments ranging from 100 to 130° C. may be desirably used. For example, Fluorinert (trademark and manufactured by 3M), Galden (trademark and manufactured by SOLVAY SOLEXIS), or the like may be used.

The etching apparatus 10 also includes a holding unit 19 which holds a processing subject such as a wafer, a heating unit 20 which heats the processing subject held by the holding unit 19 during a heating process after etching the processing subject, a temperature measuring unit 21 which measures the temperature of the processing subject, and a pressure measuring unit 22 which measures the pressure inside the reaction chamber 11. These units are all equipped inside the reaction chamber 11. Here, for example, a lamp heater may be used as the heating unit 20; a thermocouple, an infrared thermometer, or the like may be used as the temperature measuring unit 21. As the pressure measuring unit 22, a vacuum gauge such as a total pressure gauge, for example a pirani gauge or an ionization vacuum gauge, or such as a partial pressure gauge, for example, a quadrupole type mass spectrometer may be used.

Further, the etching apparatus 10 is equipped with a control unit 30 that performs an etching process by controlling the etching apparatus 10 in accordance with a program provided in advance. The control unit 30 includes a gas introduction control unit 31, an etching control unit 32, a temperature control unit 33, a gate valve control unit 34, a sublimation completion determining unit 35, and a sublimation-amount-dependent change information storing unit 36.

The gas introduction control unit 31 controls the on/off state of introduction of a reaction gas into the reaction chamber 11 by controlling the open/close state of the gas valves V1 to V4 equipped on the pipes 13-1 to 13-4 in accordance with a program provided in advance, and adjusts the supply flow rate by controlling a mass flow controller (not shown). For example, in a reaction product forming process, the gas introduction control unit 31 performs control such that N₂ gas, NH₃ gas, N₂ gas, and NF₃ gas are respectively supplied from the first to fourth pipes 13-1 to 13-4 into the reaction chamber 11 by opening the gas valves V1 to V4. In a sublimation process, the gas introduction control unit 31 performs control such that the supply of NH₃ gas and NF₃ gas from the second and fourth pipes 13-2 and 13-4 into the reaction chamber 11 is stopped and only the supply of N₂ gas from the first and fourth pipes 13-1 and 13-3 into the reaction chamber 11 is performed by closing the gas valves V2 and V4.

The etching control unit 32 operates the applicator 14 (the microwave application unit) to activate NH₃ gas when NH₃ gas is supplied toward the second pipe 13-2, in accordance with a program provided in advance so that the NH₃ gas is activated.

The temperature control unit 33 controls the temperature inside the reaction chamber 11 (or the temperature of the processing subject held by the holding unit 19) during an etching process. Specifically, the temperature control unit 33 performs a process in which the inside of the reaction chamber 11 or the processing subject is heated by the heating unit 20, or cooled by refrigerant flowing through the cooling pipe 16 so that the temperature measured by the temperature measuring unit 21 becomes a predetermined temperature in accordance with a program provided in advance. For example, in the reaction product forming process, the reaction chamber 11 is cooled by circulating the refrigerant through the cooling pipe 16 without operating the heating unit 20 used for a heating operation so that the temperature inside the reaction chamber 11 becomes a normal temperature of about 30° C. In a sublimation process following the reaction product forming process, the inside of the reaction chamber 11 is heated by the heating unit 20 so that the temperature inside the reaction chamber 11 (and hence the temperature of the processing subject) is the temperature in the range of 100 to 130° C. or higher.

The gate valve control unit 34 adjusts the opening degree of the gate valve GV so as to change the vacuum degree inside of the reaction chamber 11 to a predetermined degree in accordance with a program provided in advance. Accordingly, the amount of gas exhausted from the reaction chamber 11 by the vacuum pump 12 is then adjusted. Furthermore, the gas introduction control unit 31, the etching control unit 32, the temperature control unit 33, and the gate valve control unit 34 constitute switching unit.

The sublimation-amount-dependent change information storing unit 36 stores a predetermined physical amount which changes depending on the sublimation degree of the reaction product when the reaction product, which has been formed through the reaction product process, undergoes heating and sublimation, as sublimation-amount-dependent change information. Examples of the sublimation-amount-dependent change information include a change in pressure (physical amount) with respect to the sublimation time when the opening degree of the valve is set to be constant, a change in opening degree (physical amount) of the valve with respect to the sublimation time when the pressure is set to be constant, and a change in concentration (amount) of SiF₄, NH₃, or NF₃ with respect to the sublimation time when a quadrupole type mass spectrometer is equipped as the pressure measuring unit 22. Furthermore, the sublimation-amount-dependent change information storing unit 36 constitutes a sublimation completion determination value storing unit.

The sublimation completion determining unit 35 determines whether the amount of the reaction product remaining of the processing subject reaches a predetermined value or smaller by monitoring the sublimation-amount-dependent change value, which changes along with the sublimation of the reaction product when the reaction product formed through etching is heated and sublimated. For example, the determination may be performed depending on whether a change in monitored sublimation-amount-dependent change value over time matches the behavior of the sublimation-amount-dependent change information stored in the sublimation-amount-dependent change information storing unit 36. Specifically, when the reaction product remains, the principle is used in which the pressure inside the reaction chamber 11 increases with the sublimation, and whether the sublimation of the reaction product is completed is determined by tracking a change in pressure. Furthermore, the sublimation completion determining unit 35 constitutes a sublimation amount determining unit and a sublimation completion determining unit.

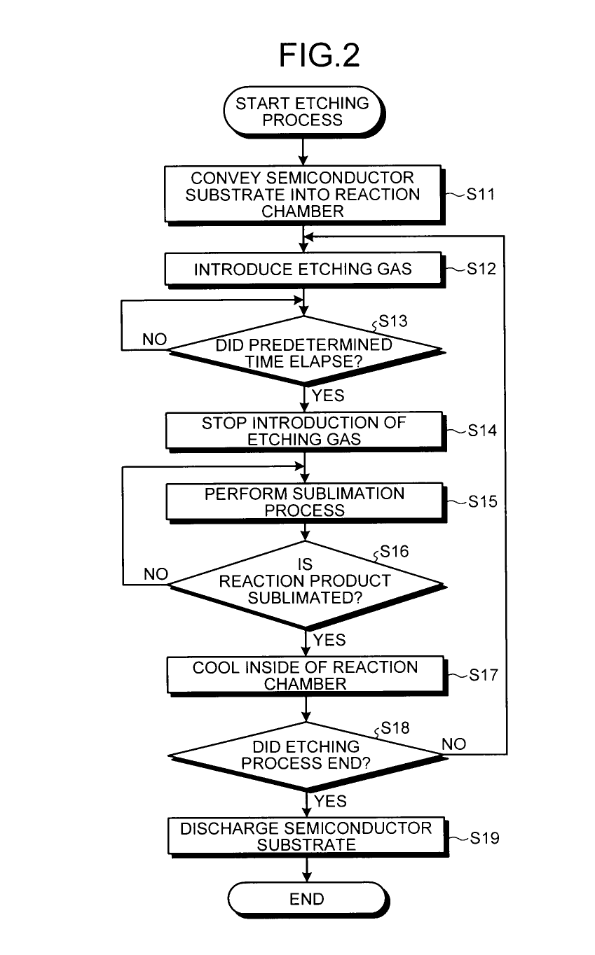

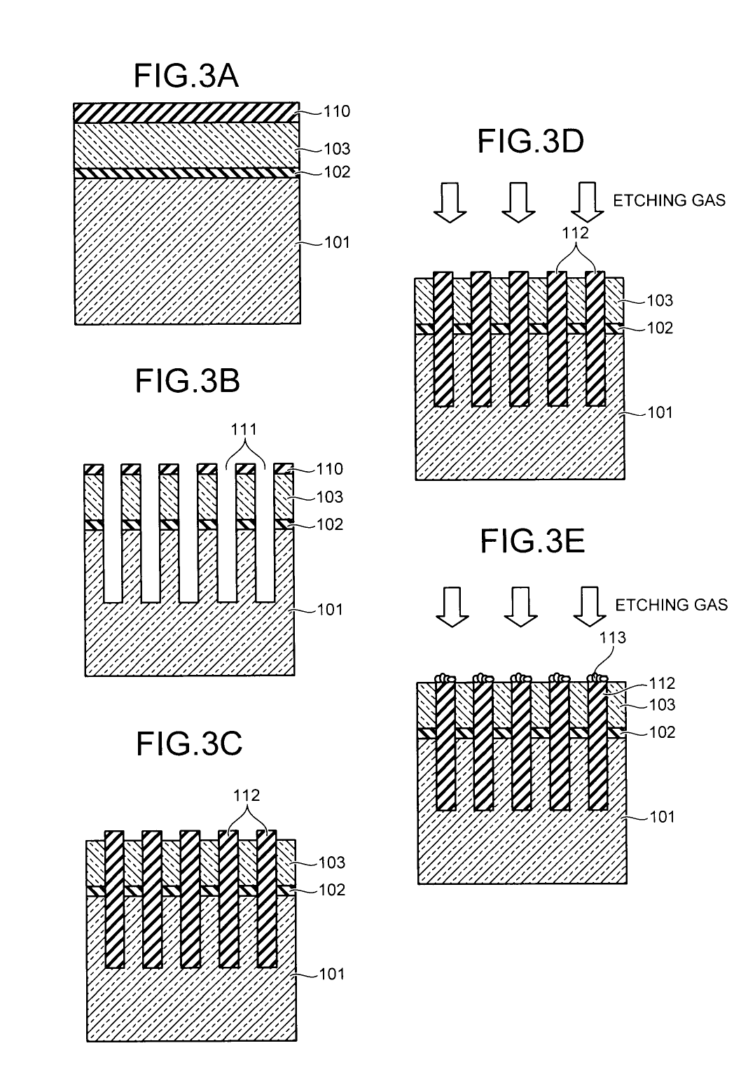

Next, the etching method will be described. FIG. 2 is a flowchart illustrating an example of a procedure of an etching method according to an embodiment, and FIGS. 3A to 3J are cross-sectional views schematically illustrating an example of a procedure of the etching method according to the embodiment. Furthermore, here, as a method of manufacturing a semiconductor device, a method of manufacturing a nonvolatile semiconductor memory device, particularly a method of forming an element isolating film will be described as an example.

First, as shown in FIG. 3A, a gate insulating film 102, a floating gate electrode film 103, and a mask film 110 are sequentially formed on a semiconductor substrate 101 such as a silicon substrate. As the gate insulating film 102, for example, a thermally-oxidized film with a film thickness of 10 nm or so may be used by using, for example, a thermal oxidation technique. Further, an example of the floating gate electrode film 103 includes a polycrystalline silicon doped with phosphorus film formed by a method such as low-pressure Chemical Vapor Deposition (CVD), having a film thickness of 70 to 80 nm or so. Furthermore, the mask film 110 is formed of a material which may etch the floating gate electrode film 103 to the semiconductor substrate 101 by a predetermined depth. As the mask film 110, for example, a silicon nitride film formed by a method such as a low-pressure CVD method and having a film thickness of 70 nm or so may be used.

Next, resist (not shown) is coated on the mask film 110, and the resist is patterned into a predetermined shape by a lithography technique. Here, a resist pattern extending in a predetermined direction (a bit line direction) and having a line-and-space shape is formed on a memory cell formation area.

Subsequently, as shown in FIG. 3B, a pattern is transferred to the mask film 110 using the resist pattern as a mask through, for example, an etching technique such as an RIE method, and then the floating gate electrode film 103, the gate insulating film 102, and the semiconductor substrate 101 are etched by a predetermined depth using the mask film 110 as a mask. Accordingly, a plurality of trenches 111, extending in the bit line direction and reaching a predetermined depth of the semiconductor substrate 101, is formed in parallel to each other.

Next, as shown in FIG. 3C, an element isolating film 112 is formed so as to fill the trenches 111. Specifically, a heat treatment is performed in the oxygen atmosphere so as to form a thin oxide film on the inner wall surface of the trench 111, and the silicon oxide film as the element isolating film 112 is deposited into the trenches 111 so as to fill the trenches in accordance with a method such as High Density Plasma (HDP). Subsequently, the element isolating film 112 formed above the top surface of the mask film 110 is removed using the mask film 110 as a stopper by a CMP method. Then, the mask film 110 is selectively removed by, for example, wet etching.

The semiconductor substrate 101 having the element isolating film 112 formed by the above-described process becomes a processing subject, and the semiconductor substrate 101 is held by the holding unit 19 of the etching apparatus 10. Then, the holding unit 19 is conveyed from the outside of the reaction chamber 11 into the reaction chamber 11 by a conveying mechanism (not shown) (step S11). The inside of the reaction chamber 11 is set to have a predetermined vacuum degree which is created through an exhausting operation by the vacuum pump 12 and the opening degree of the gate valve GV.

Next, as shown in FIGS. 3D and 3E, an etching gas is introduced into the reaction chamber 11, and a reaction product forming process from the processing subject is performed (step S12). Specifically, the first to fourth gas valves V1 to V4 are opened by the gas introduction control unit 31, and N₂ gas, NH₃ gas, and NF₃ gas are introduced into the reaction chamber 11. The supply amount of each gas is controlled by the gas introduction control unit 31 in accordance with a predetermined condition. Further, the applicator 14 is operated by the etching control unit 32, so that NH₃ gas supplied into the reaction chamber 11 is activated. Furthermore, the valves V5 and V6 are opened by the temperature control unit 33, so that refrigerant is circulated inside the reaction chamber 11 so it remains at a normal temperature of about 30° C.

In the reaction chamber 11 in such a condition, as shown in FIG. 3E, the etching gas (NH₃ gas and NF₃ gas) contacts the processing subject, so that a reaction product 113 is formed on the surface of the processing subject. Specifically, NH₃ gas and NF₃ gas are activated so as to cause a reaction with the silicon oxide film (the element isolating film 112), so that (NH₄)₂SiF₆ is formed on the element isolating film 112 as the reaction product 113. Further, since the temperature of the reaction chamber 11 is set to a normal temperature, the reaction between the silicon oxide film and the etching gas (NH₃ gas and NF₃ gas) is promoted. Furthermore, the etching time (the time for which the processing subject is exposed to the etching gas) is adjusted to an extent that the granular reaction product 113 does not grow thickly between the etching gas and the silicon oxide film.

The gas introduction control unit 31 determines whether the processing subject is exposed to the etching gas for a predetermined time (step S13). When the predetermined time is not elapsed (the case of No in step S13), it is in a standby state until the predetermined time is elapsed. After the reaction has been performed for the predetermined time (the case of Yes in step S13), the supply of the etching gas into the reaction chamber 11 is stopped (step S14), and the sublimation process is performed (step S15). Here, first, as the process of stopping the supply of the etching gas in step S14, the gas introduction control unit 31 introduces N₂ gas into the reaction chamber 11 by closing the second and fourth gas valves V2 and V4 and to keeping the first and third gas valves V1 and V3 to open, and the reaction chamber 11 is exhausted by the vacuum pump 12 so that the inside thereof reaches a predetermined vacuum degree. Subsequently, as to the sublimation process of step S15, the temperature control unit 33 closes the valves V5 and V6 so as to stop the circulation of refrigerant, and turns on the heating unit 20 so as to heat the inside of the reaction chamber 11. Furthermore, since the sublimation temperature of the reaction product (NH₄)₂SiF₆ is from 100 to 130° C., the heating unit 20 is controlled so that the temperature of the processing subject reaches the range of 100 to 130° C. or exceeds the range.

In the sublimation process, when the heating by the heating unit 20 begins, the temperature of the processing subject increases. Since the temperature of the processing subject becomes equal to or higher than the sublimation temperature of the reaction product, the reaction product (NH₄)₂SiF₆ formed on the processing subject is sublimated. The sublimation process is performed until the sublimation completion determining unit 35 determines that there is hardly the remaining amount of the reaction product 113 in the reaction chamber 11.

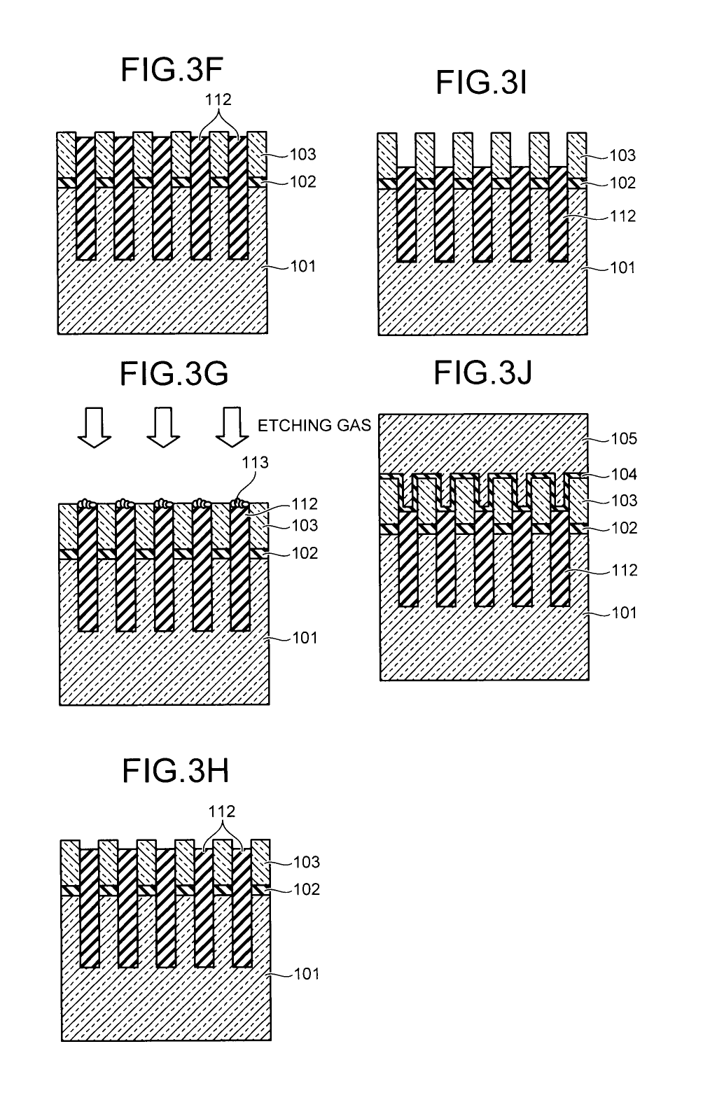

Here, a case is exemplified in which the remaining amount of the reaction product 113 is determined by monitoring the pressure value inside the reaction chamber 11 while the opening degree of the gate valve GV is set to a predetermined value. FIG. 4 is a graph schematically illustrating a condition of the pressure inside the reaction chamber during the sublimation process. In this drawing, the abscissa axis indicates a time, and the longitudinal axis indicates a pressure. As depicted by the solid curve C1 of the drawing, the pressure inside the reaction chamber 11 is set to be constant at a predetermined pressure p₁ before the sublimation process. However, when the sublimation process is performed, the pressure inside the reaction chamber 11 momentarily increases up to, for example, a maximal value p₂ due to sublimation of the reaction product 113. Since the reaction product 113 is removed (sublimated) due to the sublimation, the pressure inside the reaction chamber 11 decreases and returns to the original pressure p₁ again. Likewise, as a general routine, the pressure sharply increases from the predetermined value p₁ up to the maximal value p₂ during the sublimation process and returns to the predetermined value p₁.

Therefore, a general change in pressure inside the reaction chamber 11 with respect to the time when making the opening degree of the gate valve GV constant is stored as the sublimation-amount-dependent change information in the sublimation-amount-dependent change information storing unit 36. Then, the sublimation completion determining unit 35 determines whether the reaction product 113 is almost completely removed by checking if the pressure changes as in the case of the sublimation-amount-dependent change information (step S16).

Specifically, the sublimation completion determining unit 35 monitors the pressure inside the reaction chamber 11 using the pressure measuring unit 22, and determines whether a change in pressure over time is behaving corresponding to the sublimation-amount-dependent change information stored in the sublimation-amount-dependent change information storing unit 36 and the pressure becomes a predetermined pressure value. For example, it is determined whether the pressure value increases from p₁ to p₂ and then decreases to p₁ again over time as illustrated in the curve C1 of FIG. 4. That is, when the pressure value has a behavior that the value varies from the maximal value to a value which is used to determine that the sublimation is completed (hereinafter, referred to as a sublimation completion determination value, for example, p₁), it is determined that the reaction product 113 is almost sublimated.

When the pressure value does not reach the maximal value or the pressure value reaches the maximal value, but does not return to the sublimation completion determination value through the determination method (the case of No in step S16), it is determined that the sublimation is not completely performed yet, and the process returns to step S15. Further, when the pressure value reaches the maximal value and then returns to the sublimation completion determination value (the case of Yes in step S16), as shown in FIG. 3F, it is determined that the sublimation is almost completed, and the temperature control unit 33 cools the reaction chamber 11 (step S17). Specifically, the temperature control unit 33 turns off the heating unit 20, and starts the circulation of refrigerant by opening the valves V5 and V6 so that the reaction chamber 11 is cooled to room temperature.

Furthermore, when the sublimation of the reaction product 113 on the processing subject is hardly performed due to an intrinsic error or the like of the apparatus and the pressure gradually increases as in, for example, the dotted curve C2 of FIG. 4, the next process is performed after the pressure value reaches a maximal value p₃ and then returns to an equal or smaller value than the sublimation completion determination value. Further, when the pressure value does not become equal to or smaller than the sublimation completion determination value even when a predetermined time is elapsed after stopping the introduction of the etching gas in step S14, an abnormality is determined to have occurred. In this case, the control unit 30 may notify a user of an alarm, and the process should be stopped.

Further, the sublimation completion determining method is not limited to the above-described example, and various methods may be used. For example, the sublimation completion may be determined when the pressure value becomes a certain maximal value and then becomes a certain minimal value (a value different from the sublimation completion determination value), or the sublimation completion may be simply determined when the pressure value decreases to the sublimation completion determination value.

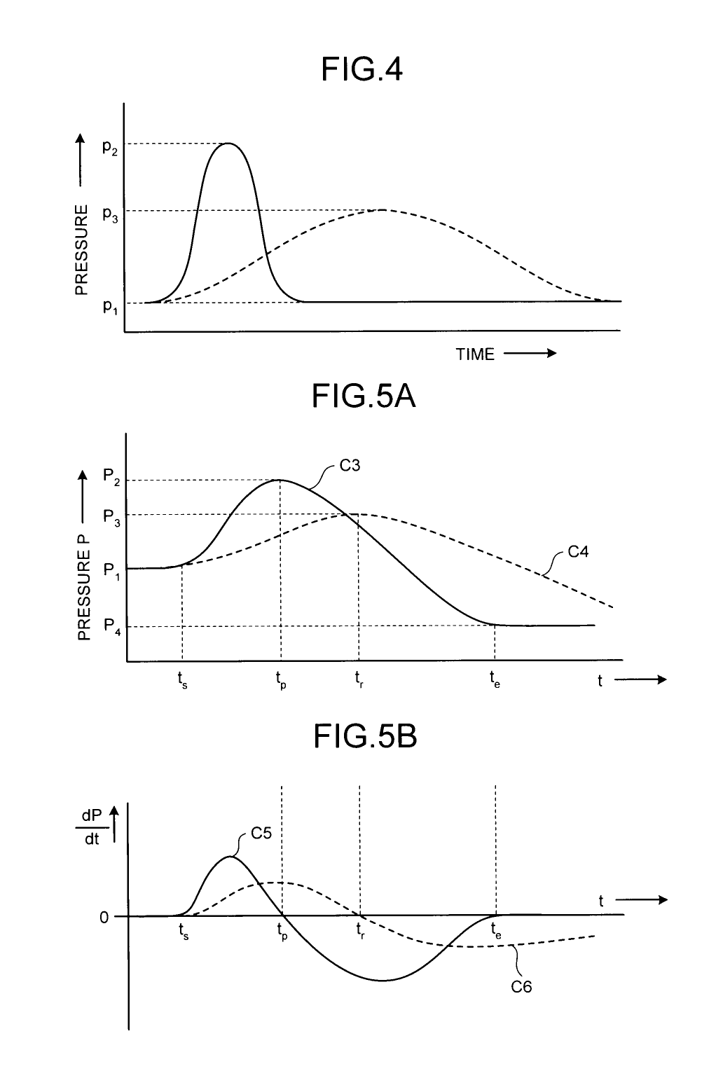

Further, the determination may be performed by the differentiation value of the pressure instead of the pressure value. FIGS. 5A and 5B are graphs schematically illustrating a condition of a pressure and a differentiation value of the pressure inside the reaction chamber during the sublimation process. FIG. 5A is a graph illustrating an example of the change in pressure over time, where the abscissa axis indicates time and the longitudinal axis indicates pressure. Further, FIG. 5B is a graph illustrating the change in differentiation values of pressure of FIG. 5A with respect to time, where the abscissa axis indicates the time and the longitudinal axis indicates the differentiation values of pressure with respect to time.

As depicted by the solid curve C3 of FIG. 5A, the pressure inside the reaction chamber 11 is set to be constant at a predetermined pressure p₁. However, when the sublimation process starts from a time tₛ, the pressure inside the reaction chamber 11 momentarily increases due to the sublimation of the reaction product 113, meets a maximal value p₂ at a time tₚ, and then decreases toward a predetermined pressure p₄. Then, the pressure becomes substantially constant as p₄ after a time tₑ at which the reaction ends. When the differentiation value with respect to time is obtained in the pressure curve, the solid curve C5 shown in FIG. 5B is obtained. The differentiation value of the pressure becomes 0 when the pressure is constant before the time t₅ at which the sublimation process starts, when it is the time tₚ at which the pressure meets the maximal value p₂, and when the pressure becomes constant after the time tₑ at which the reaction ends. That is, the sublimation completion may be determined when the sublimation process starts by setting the sublimation completion determination value with respect to the differentiation value of the pressure to 0 and the differentiation value of the pressure becomes 0 at the second time.

Furthermore, in the case where the sublimation of the reaction product 113 on the processing subject is difficult to perform due to an intrinsic error or the like of the apparatus and the pressure gradually increases, meets the maximal value p₃ at the time tᵣ, and gradually decreases as in, for example, the dotted curve C4 of FIG. 5A, the differentiation value of the pressure in this case becomes the dotted curve C6 of FIG. 5B. In such a case, the next process is performed after the differentiation value of the pressure becomes 0 at the first time and the differentiation value of the pressure becomes 0 at the second time. Further, when the differentiation value of the pressure does not become 0 even when the predetermined time has elapsed after the introduction of the etching gas was stopped in step S14, it is determined that abnormality has occurred. In this case, the control unit 30 may notify the user of an alarm, and the process should be stopped.

Subsequently, it is determined whether the etching process ends (step S18). Here, it is determined whether the etching process including the reaction product forming process and the sublimation process shown in step S12 to step S17 has been performed a defined number of times in accordance with the predetermined program. When the etching process has not ended (the case of No in step S18), the process returns to step S12 so as to repeat the above-described processes (FIGS. 3G and 3H). Further, when the etching process has ended (the case of Yes in step S18), as shown in FIG. 3I, the top surface of the element isolating film 112 is lowered from the top surface of the floating gate electrode film 103 by a predetermined depth. Then, the holding unit 19 is discharged to the outside from the reaction chamber 11 (step S19), and the etching process ends.

In one cycle of the etching processes of step S12 to step S17, it is desirable that the amount (depth) of etching the element isolating film 112 be 3 to 100 nm. In the case of an etching amount shallower than 3 nm, it takes a very long time to obtain the final depth and it is inefficient. In the case of an etching amount deeper than 100 nm, the reaction product 113 formed during the etching process grows too much, so that there is a concern in that the etching may be locally non-uniform. For this reason, during one cycle of the etching processes, it is desirable that the etching amount be controlled to be within the above-described range.

After the etching process is performed, as shown in FIG. 3J, an inter-gate insulating film 104 and a control gate electrode film 105 are formed above the semiconductor substrate 101. For example, an Oxide-Nitride-Oxide (ONO) film may be exemplified as the inter-gate insulating film, and a polycrystalline silicon film doped with phosphorus may be exemplified as the control gate electrode film 105. Subsequently, although not shown in the drawings, etching is performed from the control gate electrode film 105 to the gate insulating film 102 so as to have a pattern of a line-and-space shape extending in the direction (the word line direction) different from the bit line direction by a lithography technique and an etching technique. An inter-layer isolating film is embedded in the etched area afterwards. Accordingly, a nonvolatile semiconductor memory device is obtained.

Furthermore, in the description above, a case has been described in which the pressure value inside the reaction chamber 11 is used as the sublimation-amount-dependent change value, but when a control is performed such that the pressure value inside the reaction chamber 11 is maintained at a predetermined value, the opening degree of the gate valve GV may be used as the sublimation-amount-dependent change value. That is, when the gate valve control unit 34 controls the opening degree of the gate valve GV so that the value obtained by the pressure measuring unit 22 becomes constant, the sublimation completion determining unit 35 may monitor the opening degree of the gate valve GV over time and determine whether the reaction product 113 is sublimated on the basis of the monitored result.

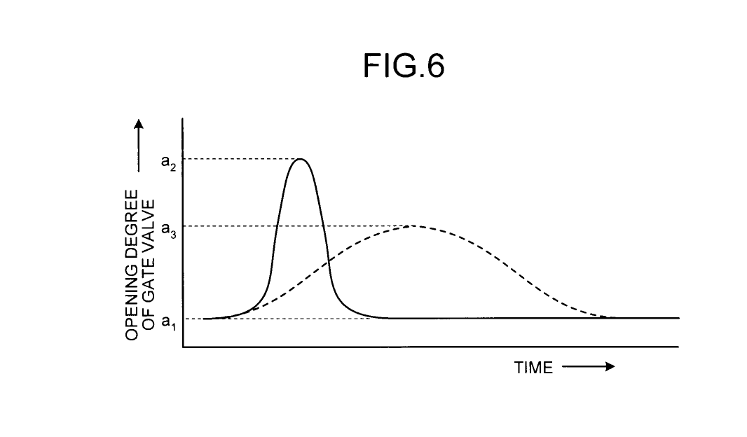

FIG. 6 is a diagram schematically illustrating a condition of an opening degree of a gate valve during the sublimation process. In this drawing, the abscissa axis indicates time and the longitudinal axis indicates the opening degree of the gate valve GV. As depicted by the solid curve C7, generally, the gate valve GV is opened by a predetermined opening degree (the opening degree not fully opened) a₁ so as to maintain the pressure inside the reaction chamber 11 at a constant value. When the sublimation process is performed, the pressure inside the reaction chamber 11 temporarily increases due to the sublimation of the reaction product. Then, in order to maintain constant pressure inside the reaction chamber 11, the opening degree of the gate valve GV is controlled by the gate valve control unit 34 so that it increases (that is, a gas exhausting amount increases). As a result, the opening degree of the gate valve GV increases, to a maximal value a₂ afterwards.

The pressure inside the reaction chamber 11 decreases as the reaction product is removed by the sublimation. However, even in this case, in order to maintain constant pressure inside the reaction chamber 11, the opening degree of the gate valve GV is controlled by the gate valve control unit 34 so that it decreases (that is, the gas exhausting amount decreases). Then, the opening degree of the gate valve GV returns almost to the value a₁ obtained before the sublimation process begins. Likewise, since the opening degree of the gate valve GV changes depending on the sublimation amount of the reaction product, it may be determined that the sublimation of the reaction product is completed when the value of the opening degree of the gate valve GV increases more than the predetermined value, meets the maximal value, and returns to the sublimation completion determination value. Further, when the sublimation of the reaction product 113 on the processing subject is not nearly performed due to an intrinsic error or the like of the apparatus and the opening degree of the gate valve GV gradually increases as in, for example, the dotted curve C8 of FIG. 5, the next process is performed after the opening degree returns to the maximal value a₃ and becomes the sublimation completion determination value or smaller.

Further, even in a parameter other than the pressure value and the opening degree of the gate valve GV, if the parameter changes depending on the sublimation amount, the parameter may be used as the sublimation-amount-dependent change value. Furthermore, in the above-described example, a parameter has been exemplified which reaches the sublimation completion determination value from a predetermined value through the maximal value, but a parameter may be used which reaches the sublimation completion determination value from a predetermined value through a minimal value.

In the embodiment, the element isolating film 112 is etched by repeating the reaction product forming process of exposing the element isolating film 112 to the etching gas so as to form the reaction product and the sublimation process of sublimating the reaction product. Further, in the sublimation process, the sublimation-amount-dependent change value changing depending on the sublimation amount of the reaction product is monitored, and the next process is performed while the sublimation remainder does not remain on the processing subject. For this reason, there is an effect in that a local deviation is suppressed in height of the element isolating film 112 caused by the sublimation remainder.

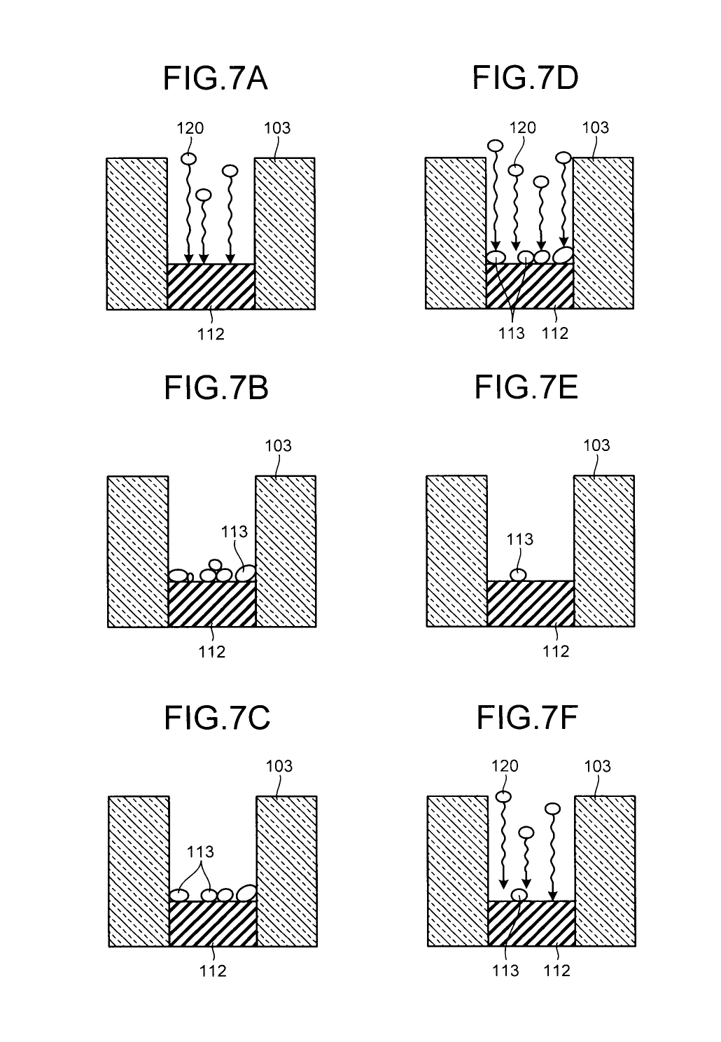

FIGS. 7A to 7F are schematic diagrams illustrating an effect of the etching method according to the embodiment. FIG. 7A schematically illustrates an etching condition of the etching gas. An etching gas 120 uniformly contacts the processing subject. As a result, as shown in FIG. 7B, the granular reaction product 113 is formed on the element isolating film 112 of the processing subject. Subsequently, the granular reaction product 113 is sublimated by the sublimation process.

At this time, for example, when a predetermined heating process is performed without monitoring the sublimation-amount-dependent change value as in the above-described embodiment, in some cases, as shown in FIG. 7C, the reaction product 113 may remain on the element isolating film 112. When the next reaction product forming process is performed in such a state, as shown in FIG. 7D, the etching gas 120 enters an area which is not covered by the reaction product 113, and the etching gas 120 may not enter the other areas. As a result, only the area which is not covered by the reaction product 113 is etched, and the other areas are not etched, thereby causing the etching to be non-uniformly performed and the height of the top surface of the element isolating film 112 to be non-uniform.

On the other hand, as in the above-described embodiment, when the sublimation process is performed by monitoring the sublimation-amount-dependent change value, the amount of the granular reaction product 113 may be made almost zero on the element isolating film 112 as shown in FIG. 7E. Then, when the reaction product 113 on the element isolating film 112 is sublimated in this manner, in the subsequent etching process, as shown in FIG. 7F, the almost all of the top surface of the element isolating film 112 is exposed, so that the etching is uniformly performed. Accordingly, a deviation may be suppressed in height of the top surface of the element isolating film 112. As a result, there is an effect in that a deviation caused by the element characteristic of the memory cell of the nonvolatile semiconductor memory device may be suppressed.

Furthermore, in the description above, a case of oxide film etching using NH₃ gas and NF₃ gas has been exemplified, but the embodiment may be applied to a case where a reaction product may be formed by a contact between a processing subject such as a silicon oxide film and an etching gas and the reaction product may be sublimated. For example, the embodiment may be applied to a case of using an oxide film etching using HF gas and NH₃ gas.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An etching apparatus comprising:
a reaction chamber;
an exhaust unit which is connected to the reaction chamber through a gate valve;
a holding unit which holds a processing subject;
an etching gas supply unit which supplies an etching gas into the reaction chamber, the etching gas forming a reaction product by reacting with the processing subject;
a heating unit which heats the processing to a temperature which is equal to or higher than a temperature at which the reaction product is sublimated; and
a sublimation amount determining unit which monitors a predetermined physical amount as a sublimation-amount-dependent change value, the physical amount changing depending on a degree of sublimation of the reaction product with a sublimation process using the heating unit.

2. The etching apparatus according to claim 1, further comprising a sublimation completion determining unit which determines whether the sublimation of the reaction product is completed based on a change in the sublimation-amount-dependent change value over time.

3. The etching apparatus according to claim 2, further comprising a switching unit which switches between a reaction product forming process of supplying an etching gas to the reaction chamber so as to form the reaction product and a sublimation process of heating the reaction product using the heating unit so as to sublimate the reaction product while the etching gas is exhausting,
wherein the switching units repeatedly executes the reaction product forming process and the sublimation process while switching between the reaction product forming process and the sublimation process, and the sublimation process is switched to the reaction product forming process when the sublimation completion determining unit makes a determination that sublimation process is completed.

4. The etching apparatus according to claim 2, further comprising a sublimation completion determination value storing unit which stores a sublimation completion determination value which is the predetermined physical amount obtained in a case where the sublimation of the reaction product is determined to be completed,
wherein the sublimation completion determining unit determines whether the sublimation of the reaction product is completed by comparing the sublimation-amount-dependent change value monitored by the sublimation amount determining unit with the sublimation completion determination value in the sublimation completion determination value storing unit.

5. The etching apparatus according to claim 1, wherein the sublimation-amount-dependent change value is the predetermined physical amount changing depending on a degree of the sublimation of the reaction product over time during the sublimation process using the heating unit.

6. The etching apparatus according to claim 2,
wherein the sublimation-amount-dependent change value is a parameter representing a behavior in which it changes to exhibit a extreme value during the sublimation process and returns to the sublimation completion determination value by which it is found that the sublimation is completed, and
the sublimation completion determining unit determines whether the sublimation of the reaction product is completed depending on whether or not the sublimation-amount-dependent change value reaches the sublimation completion determination value after reaching the extreme value.

7. The etching apparatus according to claim 6, wherein the sublimation-amount-dependent change value is a pressure inside the reaction chamber when the opening degree of the gate valve is set to be constant, or an opening degree of the gate valve when the pressure inside the reaction chamber is set to be constant.

8. The etching apparatus according to claim 1,
wherein the processing subject is a silicon oxide film, and
the etching gas supply unit supplies the etching gas containing NH₃ gas and NF₃ gas or the etching gas containing HF gas and NH₃ gas into the reaction chamber.

9. The etching apparatus according to claim 8, further comprising a mass analyzing unit which measures a pressure inside the reaction chamber,
wherein the sublimation-amount-dependent change value is a concentration or an amount of SiF₄, NH₃, or NF₃.

10. An etching method comprising:
forming a reaction product on a surface of a processing subject by disposing the processing subject in an etching gas atmosphere, in which an etching gas reacts with the processing subject to thereby form the reaction product, for a predetermined time;
sublimating the reaction product by disposing the processing subject in an atmosphere without containing the etching gas; and
repeating a procedure ranging from the forming of the reaction product to the sublimating of the reaction product,
wherein the sublimating of the reaction product includes a process of monitoring a predetermined physical amount which changes depending on a degree of the sublimation of the reaction product due to the sublimation process, as a sublimation-amount-dependent change value.

11. The etching method according to claim 10, wherein the sublimating of the reaction product further includes determining whether the sublimation of the reaction product is completed based on a change in the sublimation-amount-dependent change value over time, which is obtained through the monitoring.

12. The etching method according to claim 11, wherein, the switching to the forming of the reaction product which follows the sublimating of the reaction product is performed after it is determined that the sublimating is completed.

13. The etching method according to claim 11, wherein in the determining of the completion of the sublimating, a determination on whether the reaction product is sublimated is made by comparing the sublimation-amount-dependent change value, which is monitored in the monitoring of the sublimation-amount-dependent change value, with a sublimation completion determination value, which is set in advance and corresponds to the predetermined physical amount by which it is determined that the sublimation of the reaction product is completed.

14. The etching method according to claim 10, wherein the sublimation-amount-dependent change value is the predetermined physical amount that changes depending on a degree of the sublimation of the reaction product over sublimation process time in the sublimating of the reaction product.

15. The etching method according to claim 11,
wherein the sublimation-amount-dependent change value is a parameter representing a behavior in which it changes to a extreme value during the sublimating of the reaction product and returns to a sublimation completion determination value by which it is found that the sublimation is completed, and
in the monitoring of the sublimation-amount-dependent change value, it is determined whether the sublimation of the reaction product is completed depending on whether the sublimation-amount-dependent change value reaches a sublimation completion determination value after reaching the extreme value.

16. The etching method according to claim 10,
wherein the processing subject is disposed inside a reaction chamber to which an exhaust unit is connected through a gate valve, and
in the monitoring of the sublimation-amount-dependent change value, monitored as the sublimation-amount-dependent change value is either a pressure inside the reaction chamber when an opening degree of the gate valve is constant, or the opening degree of the gate valve when the pressure inside the reaction chamber constant is constant.

17. The etching method according to claim 10,
wherein the processing subject is a silicon oxide film, and
the etching gas is a gas containing NH₃ gas and NF₃ gas or a gas containing HF gas and NH₃ gas.

18. The etching method according to claim 17,
wherein the sublimation-amount-dependent change value is a concentration or an amount of SiF₄, NH₃, or NF₃.

19. The etching method according to claim 10, wherein in the sublimating of the reaction product, the processing subject is heated to a temperature being equal to or higher than a sublimation temperature of the reaction product.

20. The etching method according to claim 17, wherein in the sublimating of the reaction product, the processing subject is heated to a temperature in the range of from 100 to 130° C. or to a temperature exceeding the range.
